(19) United States
(12) Patent Application Publication
(10) Pub. No.: US 2005/0280018 A1
(43) Pub. Date: Dec. 22, 2005

(54) Light-emitting diode

(75) Inventor: Sadato Imai, Tokyo (JP)

Correspondence Address: BROWDY AND NEIMARK, P.L.L.C.;624 NINTH STREET, NW, SUITE 300, WASHINGTON, DC, 20001-5303, US

(73) Assignee: Citizen Electronics Co. Ltd., Fujiyoshida-shi (JP)

(21) Appl. No.: 11/149,425

(22) Filed: Jun. 10, 2005

(30) Foreign Application Priority Data
Jun. 10, 2004 (JP) P2004-172261

(51) Int. Cl. H01L 29/24

(52) U.S. Cl. 257/100

(57) ABSTRACT

An LED comprising a circuit board, a first electrode unit provided on a first surface of the circuit board, a second electrode unit provided on a second surface of the circuit board and electrically connected to the first electrode unit, an LED element mounted on the first electrode unit, and a resinous body bonded to the circuit board to seal the LED element and the first electrode unit, the first electrode unit positioned within the bonding surface of the circuit board and the resinous body.

### CROSS-REFERENCE TO THE RELATED APPLICATION

The application claims the priority benefit of Japanese Patent Application No. 2004-172261 filed on Jun. 10, 2004, the entire descriptions of which are incorporated herein by reference.

### BACKGROUND OF THE INVENTION

1. Field of the Invention

The present invention relates to a light-emitting diode (LED) in which it is possible to securely attach a resinous body to a circuit board for sealing a light-emitting diode (LED) element disposed on the circuit board.

2. Description of Related Art

Generally known is an LED including a circuit board provided with electrode patterns, an LED element mounted on the circuit board, and a translucent resinous body attached to the circuit board to cover the LED element (for reference, see Japanese Patent Nos. 3393089 and 3434714).

FIG. 6 illustrates a typical structure of a conventional LED. The LED 1 includes a circuit board 2, a pair of electrodes 5 and 6 disposed on opposite sides of the circuit board 2, an LED element 3 disposed on one electrode 5 and connected to another electrode 6 through a bonding wire 4, and a resinous body 7 which seals the LED element 3 and the bonding wire 4 and is attached to the circuit board 2 on which the pair of electrodes 5 and 6 are disposed.

Instead of using bonding wire(s), the LED may be disposed on the pair of electrodes through bumps.

Here, the pair of electrodes 5 and 6 which extend from the upper surface to the side and lower surfaces of the circuit board 2 are disposed to face each other with a space therebetween. The space on the upper surface of the circuit board 2 is numbered as 8.

However, the electrodes 5 and 6 made of metal and the resinous body 7 are different materials and thus, there are different thermal expansion coefficients between the electrodes and the resinous body. Therefore, when the LED is heated, the resinous body tends to separate from electrodes disposed on the circuit board at the bonding surface of the resinous body and the electrodes. In more detail, the resinous body often tends to separate from the electrodes at the bonding surface's peripheral bonding part 9 (shaded area) due to the different thermal expansion coefficients, also sometimes causing cracks of the resinous body. In a conventional LED's structure as described above, because the bonding surface having a long peripheral bonding part of the electrodes and the resinous body extends in a large area, cracking and separation of the resinous body from the electrodes tend to occur easily.

For example, when the thermal-shock test such as applying thermal cycles of −40° C. to +100° C. to a conventional LED is executed in order to confirm the strength of the LED, cracking and separation are generated especially at the peripheral bonding part. At worst, there is a possibility that the cracks and separation of resin may cause a break of LED's electrical connection such as bonding wires and bumps.

Accordingly, the conventional LEDs are susceptible to rapid change in temperature, and as a result, there is a high rate of defective products in the manufacturing stage.

### SUMMARY OF THE INVENTION

The object of the present invention is to provide an LED in which a resinous body which seals an LED element is bonded onto a circuit board with higher adhesiveness.

To accomplish the above-mentioned object, according to one embodiment of the present invention, the LED comprises a circuit board, a first electrode unit provided on a first surface of the circuit board, a second electrode unit provided on a second surface of the circuit board and connected electrically to the first electrode unit, an LED element mounted on the first electrode unit, and a resinous body bonded to the circuit board to seal the LED element and the first electrode unit.

The first electrode unit is positioned within the peripheral bonding part of the bonding surface where the circuit board and the resinous body are bonded.

### BRIEF DESCRIPTION OF THE DRAWINGS

FIG. 1 is a perspective view showing a first embodiment of an LED according to the present invention.

FIG. 2 is a sectional view of the LED shown in FIG. 1.

FIG. 3 is a perspective view showing a second embodiment of an LED according to the present invention.

FIG. 4 is a sectional view of the LED shown in FIG. 3.

FIG. 5 is a perspective view showing an assembly of the LED shown in FIG. 3.

FIG. 6 is a perspective view showing a conventional LED.

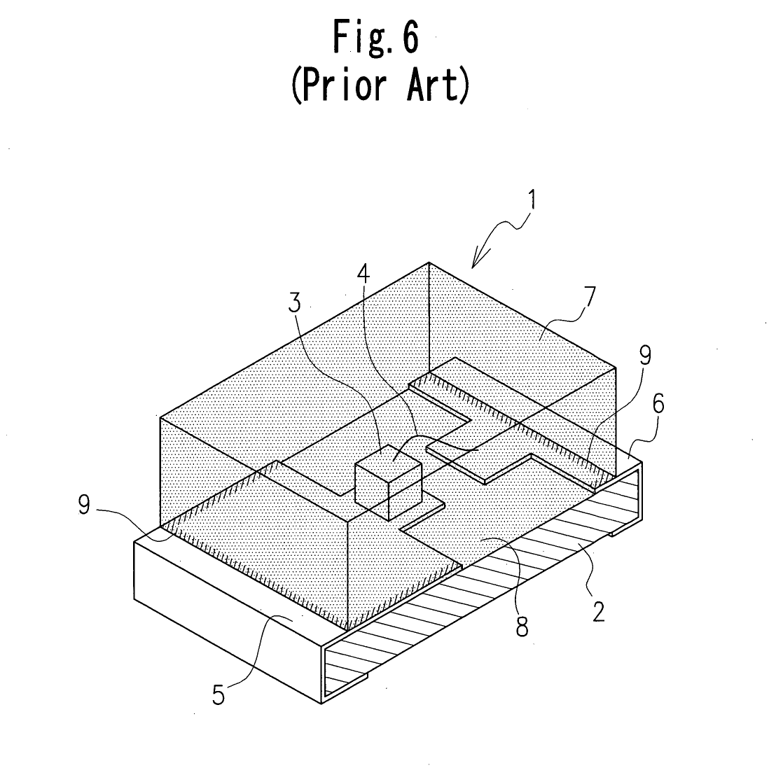

### DETAILED DESCRIPTION OF THE PREFERRED EMBODIMENTS

Preferred embodiments of the present invention will be explained with reference to the accompanying drawings below.

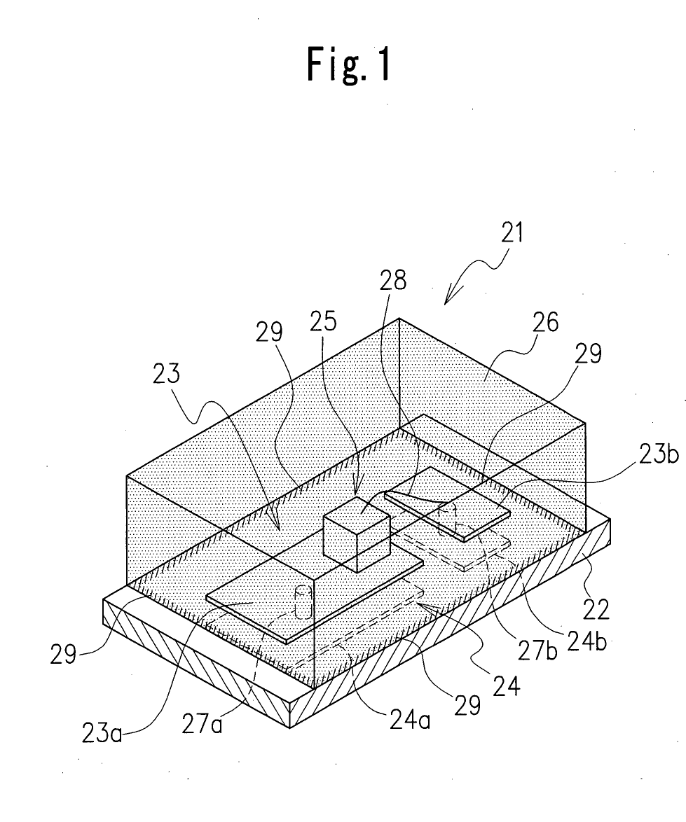

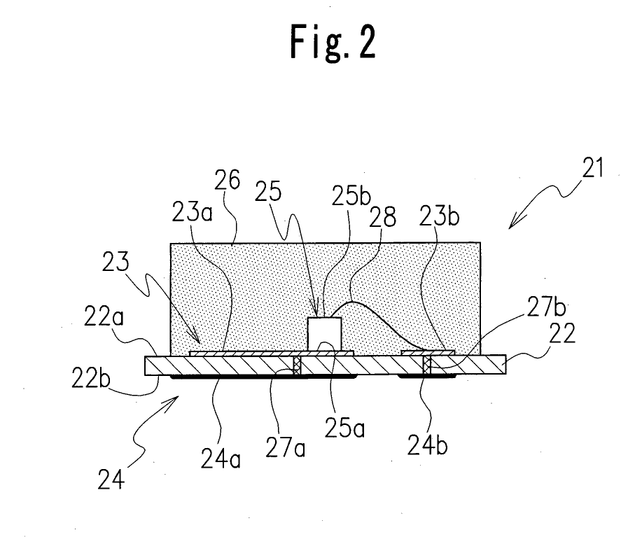

FIGS. 1 and 2 illustrate a first embodiment of an LED according to the present invention. The LED in this embodiment is numbered as 21 in FIGS. 1 and 2. The LED 21 comprises a circuit board 22, an LED element 25 mounted on the circuit board 22, and a translucent resinous body 26 to seal the LED element 25. A first electrode unit comprising a pair of electrodes or an upper electrode unit 23 is provided on a first surface of the circuit board, for example the upper surface 22a, and a second electrode unit comprising a pair of electrodes or lower electrode unit 24 is provided on a second surface of the circuit board 22, for example, the lower surface 22b (see FIG. 2).

The LED element 25 is mounted on the upper electrode unit 23 in the embodiment, as described below.

Here, Figures show an embodiment using one LED element; however, of course, a plurality of LED elements may be used according to the present invention.

The circuit board 22 is formed in a square shape from an insulating material such as glass epoxy, BT resin (Bismaleimide Triazine Resin) or the like. The upper and lower electrode units 23 and 24 are formed by etching metallic films provided on the upper and lower surfaces 22a and 22b in a predetermined patterned shape.

The upper electrode unit 23 comprises at least one anode electrode 23a and at least one cathode electrode 23b, and is patterned in the vicinity of the central portion of the upper surface 22a of the circuit board 22. The lower electrode unit 24 comprises at least one anode electrode 24a and at least one cathode electrode 24b, in a similar manner to the upper electrode unit 23. In the case of using a plurality of LED elements, each of the upper and lower electrode units may comprise a pair of anode and cathode electrodes or may comprise a plurality of pairs of anode and cathode electrodes. The anode and cathode electrodes 23a and 23b on the upper surface 22a are electrically connected with the anode and cathode electrodes 24a and 24b on the lower surface 22b by through-holes 27a and 27b, respectively (see FIG. 1).

Meanwhile, the anode and cathode electrodes 24a and 24b on the lower surface 22b need not be formed symmetrically with the anode and cathode electrodes 23a and 23b on the upper surface 22a.

The LED element 25 has a pair of electrodes 25a and 25b; one electrode 25a is mounted on the anode electrode 23a by die bonding, and the other electrode 25b is connected to the cathode electrode 23b by a bonding wire 28. In addition, the LED element 25 may be placed on the upper electrode unit 23 in such a way that the LED element is disposed to bridge the anode and cathode electrodes 23a and 23b of the upper electrode unit 23 through bumps (not shown) instead of using the bonding wire 28.

The resinous body 26 is made of a translucent epoxy or silicon-based resinous material so as to completely seal the at least one LED element 25 on the upper surface 22a of the circuit board 22 and the upper electrode unit 23. If needed, the resinous body may contain fluorescent material(s) and dye compound(s). In other words, the upper electrode unit 23 comprising at least one pair of the anode and cathode electrodes 23a and 23b, and the at least one LED element 25 are positioned within the peripheral bonding part 29 (shaded area) of the bonding surface where the upper surface 22a of the circuit board 22 and the resinous body 26 are bonded.

Accordingly, the circumference of the upper electrode unit 23 is surrounded by the bonding surface (including the peripheral bonding part 29) where the upper surface 22a on the circuit board 22 and the resinous body 26 are bonded. The bonding surface except the part of the upper electrode unit 23 is formed by a resin-to-resin connection between the circuit board and the resinous body, and the resin-to-resin connection extends as a large plane.

As described above, because the peripheral bonding part where the upper surface of the circuit board and the resinous body are bonded without the interference of the upper electrode unit is bonded in a resin-to-resin manner along the peripheral bonding part 29 of the bonding surface, the circuit board and the resinous body can be bonded with an enhanced adhesion.

In addition, because the peripheral bonding part 29 is formed by a resin-to-resin connection and the circuit board 22 and the resinous body 26 have essentially the same width and direction of expansion and contraction, cracking and separation at the peripheral bonding part 29 are eliminated even if heat is applied suddenly to the circuit board and so on in a thermal-shock test or the like. Thereby, it is possible to decrease the influence on the LED element 25 sealed in the resinous body 26 and any electrical connecting portions such as the bonding wire 28 or bumps connecting the LED element 25, and the anode and cathode electrodes 23a and 23b.

The above-mentioned LED 21 is adapted to form the upper and lower electrode units 23 and 24 having a predetermined shape by forming conductive films on the upper and lower surfaces 22a and 22b of the circuit board 22 made from resin such as glass epoxy or the like and etching the conductive films. The through-holes 27a and 27b connecting the upper and lower electrode units 23 and 24 are then formed so as to pass through the circuit board 22. The LED element 25 is then die-bonded on the anode electrode 23a of the upper electrode unit 23, and is connected to the cathode electrode 23b by the bonding wire 28. Finally, the translucent resinous body 26 is formed on the upper surface 22a of the circuit board 22 by a die or the like to cover the upper electrode unit 23 and the LED element 25, and thereby the LED is completed. The LED element 25 may be surface-mounted on the upper electrode unit 23 by way of bumps instead of using the bonding wire 28.

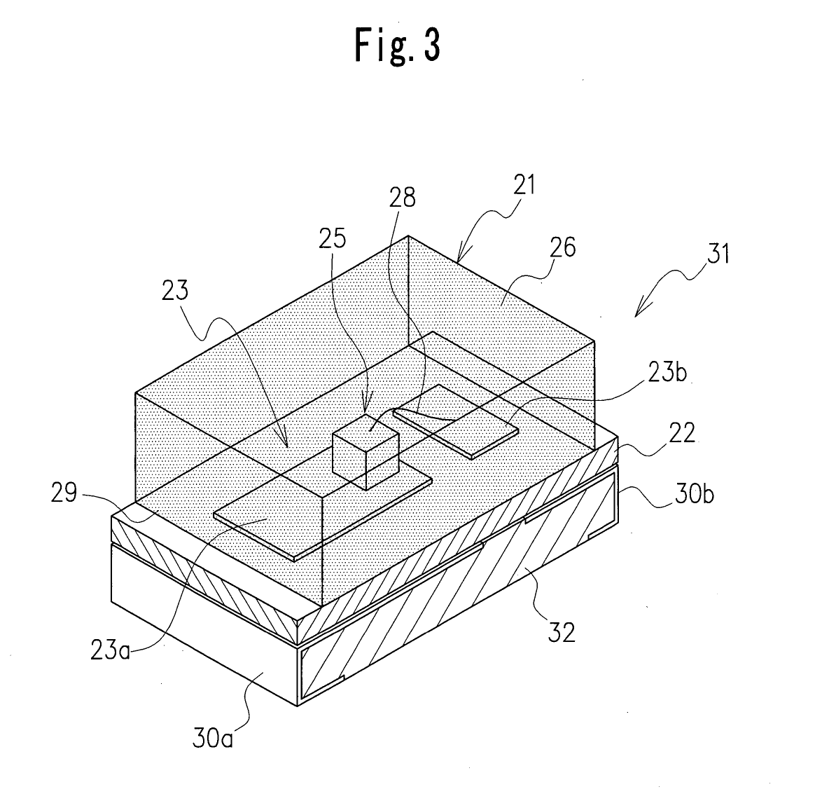

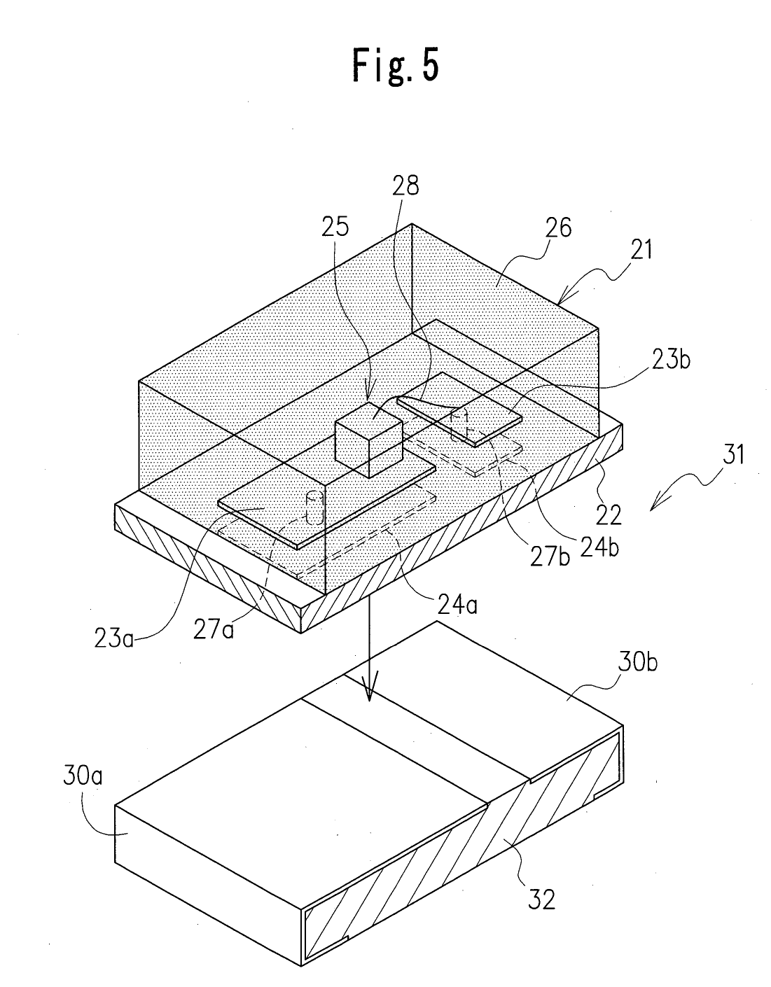

FIGS. 3 to 5 illustrate the second embodiment of the LED according to the present invention. The LED 31 in this embodiment has a structure further comprising a basic board 32 which is provided under the circuit board 22. When the LED 31 is used in an electronics device, the basic board 32 provided under the circuit board 22 of the LED 31 makes it easier to mount the LED on the circuit board of the electronics device. The circuit board of the electronics device is mentioned as a motherboard 30 here. The basic board 32 is made of an insulating material such as glass epoxy or BT resin (Bismaleimide Triazine Resin) and is roughly the same size as the circuit board 22. The basic board 32 includes a pair of electrodes 30a and 30b which are connected to the mother board 30 of the electronics device. Each of the electrodes 30a and 30b is formed to extend from one portion of the upper surface, via the side surface to one portion of the lower surface of the basic board 32.

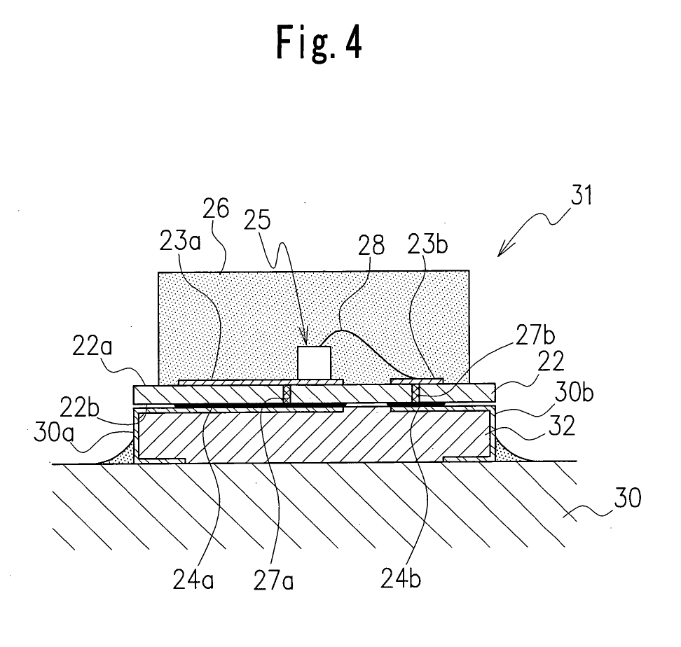

The anode and cathode electrodes 24a and 24b on the lower surface 22b of the circuit board 22 are bonded to the upper surface of the basic board 32 on which the electrodes 30a and 30b are provided. The lower surface of the basic board 32 is mounted on the motherboard 30 of an external electronics device by soldering, as shown in FIG. 4.

In the LED 31, the upper surface of the basic board 32 is bonded to the lower surface of the circuit board 22 of the LED 21 shown in the first embodiment through silver paste, or an anisotropic conductive material composed of conductive particles and an adhesive or a binder. The anisotropic conductive material has the three functions of adhesion, conductivity and insulation; the conductive particles act to connect the upper and lower electrode units electrically and the binder fulfills the role of mechanically fixing the bonding surface of the LED 21 and the basic board.

There are two kinds of this type of anisotropic conductive material, anisotropic conductive film (ACF) and anisotropic conductive paste (ACP).

The ACF is cut into pieces of predetermined length and the cut pieces are attached to the anode and cathode electrodes 24a and 24b directly, while the ACP is allowed to full in drops on the anode and cathode electrodes 24a and 24b and thereafter spread evenly thereon. The ACF and the ACP have electric anisotropy, showing conductivity in the thickness direction in the pressure-bonding portion in a thermo-compression process, while on the other hand, showing insulation in the direction along the plane of the pressure-bonding portion.

Consequently, because the circuit board 22 has conductivity in the depth direction of the through-holes 27a and 27b provided in the circuit board 22, while having no conductivity in the planar direction of the contact surface, shorting of the electrodes 30a and 30b can be effectively prevented.

Meanwhile, although the basic board 32 is the same size as the circuit board 22 in the second embodiment, if electrical connection between the lower electrode unit 24 disposed on the circuit board 22 and the electrodes 30a and 30b disposed on the basic board 32 is accomplished, the basic board 32 is not limited to the above-mentioned size and shape. Therefore, the basic board 32 may be formed corresponding to the shape and so on of the electrode pattern formed on the motherboard 30.

According to the present invention, as described above, because the upper electrode unit to which the LED element is connected is provided on the circuit board to be positioned within the resinous body for sealing the LED element, and the peripheral bonding part of the bonding surface of the circuit board and the resinous body is formed by a resin-to-resin contact surface, a higher close-fitting strength can be acquired especially at the peripheral bonding part, and even if the ambient temperature changes suddenly, there are no great differences in the expansion and contraction of the circuit board and the resinous body.

Therefore, it is possible to prevent separation and cracking of the resinous body, and deterioration of the connecting parts between the LED element and the upper electrode unit, caused by the separation and cracking of the resinous body. As a result, the present invention allows the LED to have a sufficient durability.

In addition, the mounting of the LED on a motherboard of an electronics device can be simplified because a lower electrode unit which is connected to the upper electrode unit via through-holes is provided on the lower surface of the circuit board and the lower surface of the circuit board is fixed on a basic board having electrodes provided on the surfaces of the basic board for easily connecting the LED to a motherboard of an external electronics device.

Although the preferred embodiments of the present invention have been described, the present invention is not limited to these embodiments; various changes and modifications can be made to the embodiments.

1. A light-emitting diode, comprising:
a circuit board;
a first electrode unit provided on a first surface of the circuit board;
a second electrode unit provided on a second surface of the circuit board and connected electrically to the first electrode unit;
at least one light-emitting diode element mounted on the first electrode unit; and
a resinous body bonded onto the circuit board to seal the at least one light-emitting diode element and the first electrode unit,
wherein the first electrode unit is positioned within the bonding surface where the circuit board and the resinous body are bonded.

2. The light-emitting diode according to claim 1,
wherein the bonding surface is around the entire circumference of the first electrode unit.

3. The light-emitting diode according to claim 1,
wherein the first electrode unit and the second electrode unit are connected electrically by at least two through-holes passing through the circuit board.

4. The light-emitting diode according to claim 1,
wherein each of the first electrode unit and the second electrode unit has at least one pair of anode and cathode electrodes.

5. The light-emitting diode according to claim 1,
further comprising a basic board attached to the lower surface of the circuit board,
wherein the basic board includes electrodes provided on surfaces of the basic board and the electrodes are to be connected to a motherboard of an external electronics device.

6. The light-emitting diode according to claim 5,
wherein the second electrode unit of the circuit board is connected to the electrodes provided on the basic board by using a silver paste, or a paste-like or film-like anisotropic conductive material.

7. A light-emitting diode, comprising:
a circuit board;
a first electrode unit provided on a first surface of the circuit board;
a second electrode unit provided on a second surface of the circuit board and connected electrically to the first electrode unit;
at least one light-emitting diode element mounted on the first electrode unit; and
a resinous body bonded onto the circuit board to seal the at least one light-emitting diode element and the first electrode unit,
wherein the resinous body includes an area for bonding with the first electrode unit and an area for bonding with the upper surface of the circuit board,
wherein the area of the resinous body for bonding with the first electrode unit is surrounded by the area of the resinous body for bonding with the upper surface of the circuit board.
